(19) United States
(12) Patent Application Publication
(10) Pub. No.: US 2025/0202431 A1
(43) Pub. Date: Jun. 19, 2025

(54) POWER SUPPLY CIRCUIT FOR PROVIDING MULTIPLE PAIRS OF COMPLEMENTARY POWER SUPPLY VOLTAGES AND A FIXED POWER SUPPLY VOLTAGE

(71) Applicant: QUALCOMM Incorporated, San Diego, CA (US)

(72) Inventors: Qubo ZHOU, San Diego, CA (US); Ganesh KIRAN, San Diego, CA (US)

(21) Appl. No.: 18/545,782

(22) Filed: Dec. 19, 2023

(51) Int. Cl. H03F 1/02; H02M 3/07; H03F 3/21

(52) U.S. Cl. CPC H03F 1/0233; H02M 3/07; H03F 3/21; H03F 2200/03

(57) ABSTRACT

Techniques and apparatus for supplying power are provided. One example power supply circuit generally includes a first common node for coupling to a first terminal of a capacitive element, a first switch coupled between an input voltage node and the first common node, a second switch coupled between a first power supply node and the first common node, a third switch coupled between a reference potential node and the first common node, and a fourth switch coupled between a second power supply node and the first common node. The power supply circuit may be implemented, for example, as a single charge pump with a single capacitive element, and may be configured to supply multiple sets of complementary power supply voltages (e.g., for an amplifier included in an audio system) and another power supply voltage (e.g., a fixed power supply voltage for a digital-to-analog converter included in the audio system).

### TECHNICAL FIELD

Certain aspects of the present disclosure generally relate to electronic circuits and, more particularly, to power supply circuits, such as charge pumps.

### BACKGROUND

A voltage regulator ideally provides a constant direct current (DC) output voltage regardless of changes in load current or input voltage. Voltage regulators may be classified as linear regulators or switching regulators. While linear regulators tend to be relatively compact, many applications may benefit from the increased efficiency of a switching regulator. A linear regulator may be implemented by a low-dropout (LDO) regulator, for example. A switching regulator (also known as a “switching converter” or “switcher”) may be implemented, for example, by a switched-mode power supply (SMPS), such as a buck converter, a boost converter, a buck-boost converter, or a charge pump.

A charge pump is a type of SMPS typically comprising at least one switching device to control the connection of a supply voltage across a load through a capacitor. In a voltage doubler (also referred to as a “multiply-by-two (×2) charge pump”), for example, the capacitor of the charge pump circuit may initially be connected across the supply, charging the capacitor to the supply voltage. The charge pump circuit may then be reconfigured to connect the capacitor in series with the supply and the load, doubling the voltage across the load. This two-stage cycle is repeated at the switching frequency for the charge pump. Charge pumps may be used to multiply or divide voltages by integer or fractional amounts, depending on the circuit topology.

### SUMMARY

The systems, methods, and devices of the disclosure each have several aspects, no single one of which is solely responsible for its desirable attributes. Without limiting the scope of this disclosure as expressed by the claims that follow, some features will now be discussed briefly. After considering this discussion, and particularly after reading the section entitled “Detailed Description,” one will understand how the features of this disclosure provide the advantages described herein.

Certain aspects of the present disclosure provide a power supply circuit. The power supply circuit generally includes a first common node for coupling to a first terminal of a capacitive element, a first switch coupled between an input voltage node and the first common node, a second switch coupled between a first power supply node and the first common node, a third switch coupled between a reference potential node and the first common node, and a fourth switch coupled between a second power supply node and the first common node.

Certain aspects of the present disclosure provide a power supply circuit. The power supply circuit generally includes a first common node for coupling to a terminal of a capacitive element, a first switch coupled between a first power supply node and the first common node, a second switch coupled between a reference potential node and the first common node, a third switch coupled between a second power supply node and the first common node, and a fourth switch coupled between a third power supply node and the first common node.

Certain aspects of the present disclosure provide a power supply circuit. The power supply circuit generally includes a capacitive element and a plurality of switches coupled to the capacitive element. The plurality of switches is configured to be controlled to generate: at least one of a first positive voltage or a second positive voltage at a first power supply node, the second positive voltage being different than the first positive voltage; at least one of a first negative voltage or a second negative voltage at a second power supply node, the second negative voltage being different than the first negative voltage; and a third negative voltage at a third power supply node.

Certain aspects of the present disclosure provide a circuit. The circuit generally includes an amplifier, a digital-to-analog converter (DAC), a charge pump (CP) configured to generate at least three power supply voltages, and at least three different power supply rails coupled between the CP and at least one of the amplifier and the DAC and configured to power the amplifier and the DAC with the at least three power supply voltages.

Certain aspects of the present disclosure are directed to a method of supplying power with a power supply circuit that includes a plurality of switches coupled to a capacitive element. The method generally includes controlling the plurality of switches of the power supply circuit to generate at least one of a first positive voltage or a second positive voltage at a first power supply node of the power supply circuit, the second positive voltage being different than the first positive voltage. The method also generally includes controlling the plurality of switches of the power supply circuit to generate at least one of a first negative voltage or a second negative voltage at a second power supply node of the power supply circuit, the second negative voltage being different than the first negative voltage, and controlling the plurality of switches of the power supply circuit to generate a third negative voltage at a third power supply node of the power supply circuit.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a block diagram of an example audio amplifier system, in which aspects of the present disclosure may be practiced.

FIG. 2 is a graph of an example output signal of an amplifier over time illustrating power rail switching, in accordance with certain aspects of the present disclosure.

FIG. 3 is a block diagram of an example power supply solution for a digital-to-analog converter (DAC) and amplifier, in accordance with certain aspects of the present disclosure.

FIG. 4A is a circuit diagram of an example power supply circuit architecture for implementing the first charge pump and the second charge pump of FIG. 3, in accordance with certain aspects of the present disclosure.

FIG. 4B illustrates tables that display the switching states of charge pump switches during different phases for controlling the first charge pump and the second charge pump of FIGS. 3 and 4A, in accordance with certain aspects of the present disclosure.

FIG. 5A is a circuit diagram of an example power supply circuit configured to provide the power supply voltages of FIG. 4A, in accordance with certain aspects of the present disclosure.

FIG. 5B illustrates a table that displays the operation of the switching states of the circuit switches during different phases for controlling the power supply circuit of FIG. 5A, in accordance with certain aspects of the present disclosure.

FIG. 6 is a flow diagram of example operations for supplying power with a power supply circuit, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure provide techniques and apparatus for supplying multiple pairs of complementary power supply voltages (e.g., for a power amplifier included in an audio system) and another power supply voltage (e.g., a fixed power supply voltage for a digital-to-analog converter included in the audio system) using a power supply circuit. Such a power supply circuit may be implemented, for example, as a single charge pump with a single capacitive element.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

### Example Audio System

A speaker is a transducer that produces a pressure wave in response to an input electrical signal, and thus, sound is generated. The speaker input signal may be produced by an audio amplifier (also referred to as a “power amplifier”) that receives a relatively lower voltage analog audio signal and generates an amplified signal (with a relatively higher voltage) to drive the speaker. A dynamic loudspeaker is typically composed of a lightweight diaphragm (a cone) connected to a rigid basket (a frame) via a flexible suspension (sometimes referred to as a “spider”) that constrains a voice coil to move axially through a cylindrical magnetic gap. When the input electrical signal is applied to the voice coil, a magnetic field is created by the electric current in the coil, thereby forming a linear electric motor. By varying the electrical signal from the audio amplifier, the mechanical force generated by the interaction between the magnet and the voice coil is modulated and causes the cone to move back and forth, thereby creating the pressure waves interpreted as sound.

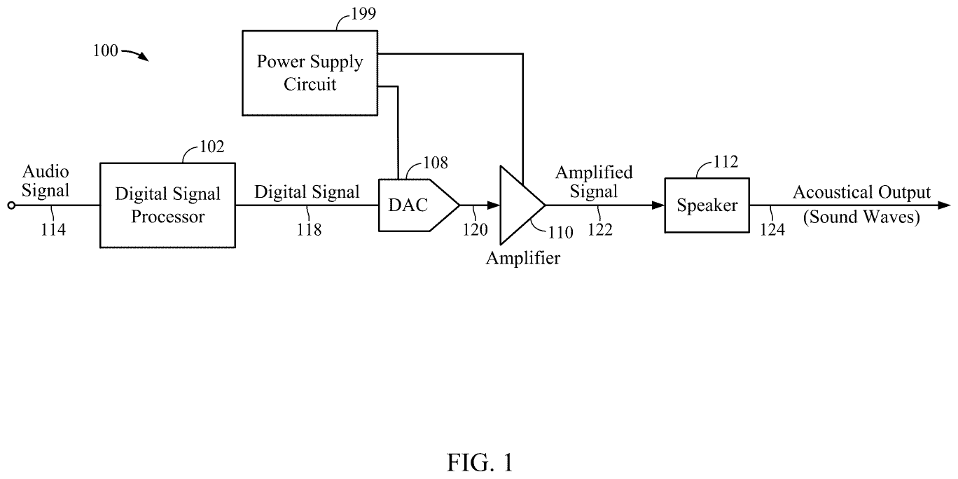

FIG. 1 illustrates an example audio system 100, in which aspects of the present disclosure may be practiced. However, it is to be understood that aspects of the present disclosure may also be practiced in any of various other suitable amplification scenarios.

As illustrated in FIG. 1, a digital signal processor (DSP) 102 may receive and process audio signals 114 (e.g., a digital audio signal) by, for example, applying a digital filter aimed at increasing audio quality. The filtered or otherwise processed digital signal 118 produced by the DSP 102 (or a further processed version thereof) may be converted to an analog signal 120 using a digital-to-analog converter (DAC) 108. In certain aspects, the DAC 108 may be implemented as part of the DSP 102 or an amplifier 110 (e.g., a power amplifier (PA)). The DSP 102 and the DAC 108 may be part of an audio coder/decoder (CODEC). In certain aspects, the analog signal 120 may be amplified using the amplifier 110 to generate an amplified signal 122. The amplified signal 122 may drive a speaker 112 to produce an acoustic output 124 (e.g., sound waves). In other words, the amplifier 110 may function as a speaker driver.

The DAC 108 and/or the amplifier 110 may be powered by a power supply circuit 199. The power supply circuit may include one or more voltage regulators (e.g., linear regulators and/or switched-mode power supplies, such as charge pumps). The power supply circuit 199 may provide a single-ended voltage and/or complementary voltages to each of the DAC 108 and/or the amplifier 110. The power supply circuit 199 may provide the same or different power supply voltages to the DAC 108 and the amplifier 110.

### Example Amplifier Operation

High output volume in mobile devices is becoming increasingly important in next-generation devices. Higher volume translates to higher audio amplifier output power. Higher output power may be difficult to achieve with the relatively low voltages provided by lithium-ion batteries. Therefore, boost converters may be used to boost the battery voltage to a higher level that supplies the audio power amplifier (e.g., amplifier 110). For certain aspects, the amplifier 110 may be implemented as a class-D amplifier due to the relatively high power efficiency associated with class-D amplifiers. The efficiency of the class-D amplifier may be further improved by implementing the class-D amplifier in an H-bridge configuration, for example. However, some class-D amplifiers may not be capable of delivering sufficiently high power due to limited battery current and/or limited battery voltage. Therefore, other amplifier architectures may be utilized in some aspects to deliver high power.

Other amplifier types capable of delivering high power include class-H and class-G amplifiers, in which the power supply rail is varied to follow the input speaker signal (referred to as “rail voltage modulation”), where the input speaker signal may be the amplified signal 122. In class-H amplifiers, the power supply rail is continuously variable, whereas in class-G amplifiers, there may be different discrete levels for the power supply rail to switch between, based on the input speaker signal. Class-H amplifiers are sometimes referred to as “rail trackers” because the amplifiers modulate the supply rails so that the rails are only a few volts larger than the amplifier output signal, “tracking” this signal at any given time. Class-G amplifiers, on the other hand, may have multiple power rails at different voltage levels and may switch between the rails as the output signal approaches each level.

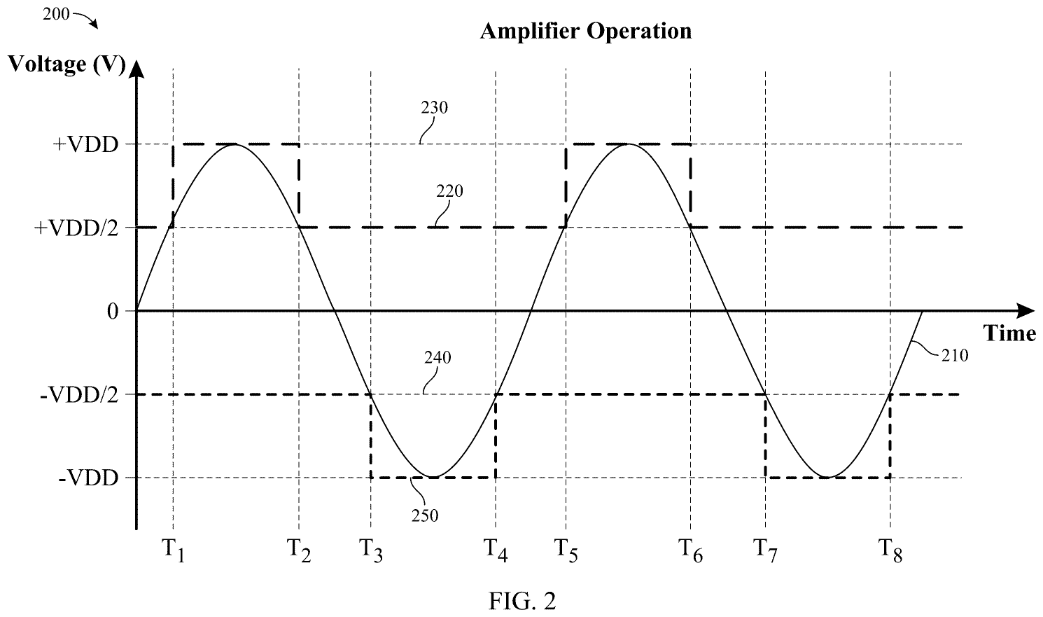

FIG. 2 is a graph of an example output signal 210 of an amplifier (e.g., amplifier 110, implemented as a Class-G amplifier) over time illustrating power rail switching, in accordance with certain aspects of the present disclosure.

According to certain aspects of the present disclosure, the amplifier 110 may switch between several power supply rails at different voltage levels (e.g., a first power supply rail 220 at a voltage level of +VDD/2, a second power supply rail 230 at a voltage level of +VDD, a third power supply rail 240 at a voltage level of −VDD/2, and a fourth power supply rail 250 at a voltage level of −VDD) as the amplifier output signal 210 approaches each voltage level. For example, the amplifier 110 may initially be operating using the first power supply rail 220 and may be configured to switch to the second power supply rail 230 when the output signal 210 is increasing and approaches the voltage level of +VDD/2 (e.g., at time T₁, T₅). In these examples, the amplifier 110 may be configured to switch back from the second power supply rail 230 to the first power supply rail 220 when the output signal 210 is decreasing and again approaches the voltage level of +VDD/2 (e.g., at time T₂, T₆). In another example, the amplifier 110 may be operating using the third power supply rail 240 and may be configured to switch from the third power supply rail 240 to the fourth power supply rail 250 when the output signal 210 is decreasing and approaches the voltage level of −VDD/2 (e.g., at time T₃, T₇). In these examples, the amplifier 110 may be configured to switch back from the fourth power supply rail 250 to the third power supply rail 240 when the output signal 210 is increasing and again approaches the voltage level of −VDD/2 (e.g., at time T₄, T₈). In this manner, the amplifier 110 may consume less power than if the amplifier always operated with the first and fourth power supply rails, resulting in increased efficiency.

### Example Power Supply Architectures

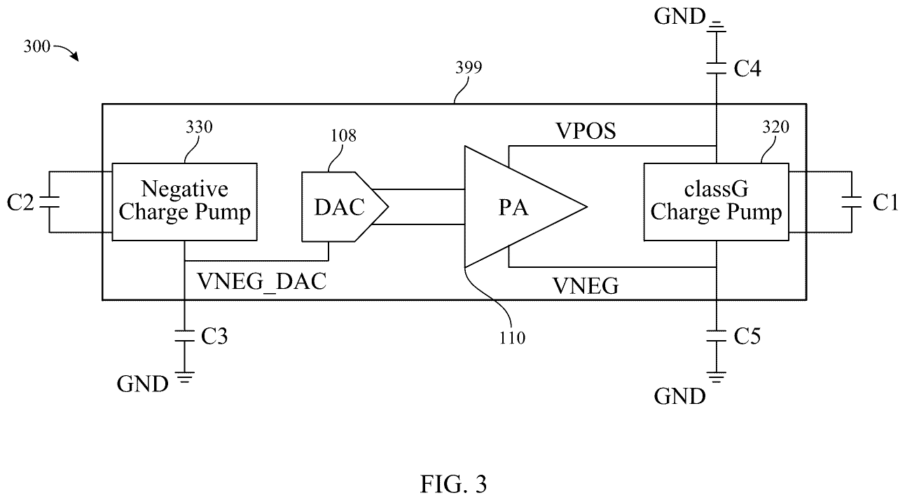

FIG. 3 is a block diagram of an example power supply architecture 300 for the power supply circuit 199 of FIG. 1, in accordance with certain aspects of the present disclosure.

The power supply architecture 300 may include a first charge pump 320 (labeled “class-G charge pump”) with a first capacitive element C1 and a second charge pump 330 (labeled “negative charge pump” (NCP)) with a second capacitive element C2. The first capacitive element C1 and the second capacitive element C2 may also be referred to as “switched capacitors” or “flying capacitors.” Each of the first capacitive element C1 and the second capacitive element C2 may be implemented by one or more capacitors. As illustrated in FIG. 3, the first charge pump 320 has outputs coupled to the power supply inputs of the amplifier 110 (labeled “PA”) and is configured to generate the power supply voltages for the amplifier 110. The second charge pump 330 has an output coupled to the power supply input of the DAC 108 and is configured to generate the power supply voltage for the DAC 108. Thus, the amplifier 110 may be powered by a pair of complementary power supply rails (e.g., a first power supply node labeled “VPOS” and a second power supply node labeled “VNEG”), which may support class-G/class-AB amplifier operation. The DAC 108 may be powered by a single-ended power supply rail (e.g., a third power supply node labeled “VNEG_DAC”). The first power supply node VPOS, the second power supply node VNEG, and the third power supply node VNEG_DAC may each be coupled to a terminal of one of bypass capacitive elements C3, C4, and C5, respectively, as illustrated. The other terminal of each of the bypass capacitive elements C3, C4, and C5 is coupled to a reference potential node (e.g., electrical ground, labeled “GND”), as illustrated.

The first charge pump 320 with the first capacitive element C1 may be used to generate one of multiple positive voltages at the first power supply node VPOS and one of multiple negative voltages at the second power supply node VNEG for powering the amplifier 110. By selecting between the multiple voltages, the output of the first charge pump 320 with the first capacitive element C1 may be considered a dynamic voltage. In certain aspects, the power supply voltages output by the first charge pump 320 with the first capacitive element C1 may be complementary voltages.

As illustrated in FIG. 3, the second charge pump 330 with the second capacitive element C2 may be used to generate one or more negative voltages at the third power supply node VNEG_DAC for powering the DAC 108. In other aspects, the second charge pump 330 with the second capacitive element C2 may be used to generate one or more positive voltages, which may be coupled to a different power supply node. In certain aspects, the output of the second charge pump 330 may be a single, fixed voltage (e.g., a fixed negative voltage).

The DAC 108, the amplifier 110, most of the components of the first charge pump 320, and most of the components of the second charge pump 330 may be implemented in an integrated circuit (IC) 399, as depicted in FIG. 3. The capacitive element C1 associated with the first charge pump 320 and/or the capacitive element C2 associated with the second charge pump 330 may be external to the IC 399. Similarly, the bypass capacitive elements C3, C4, and/or C5 may also be external to the IC 399, as shown.

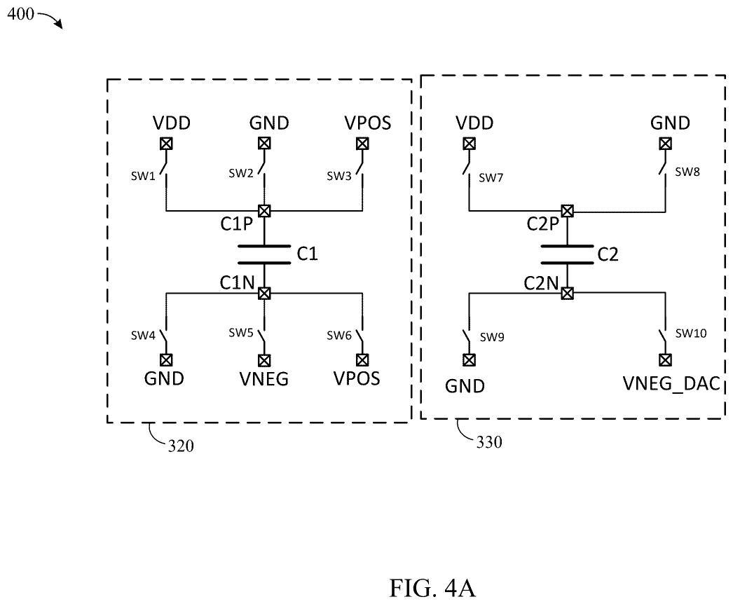

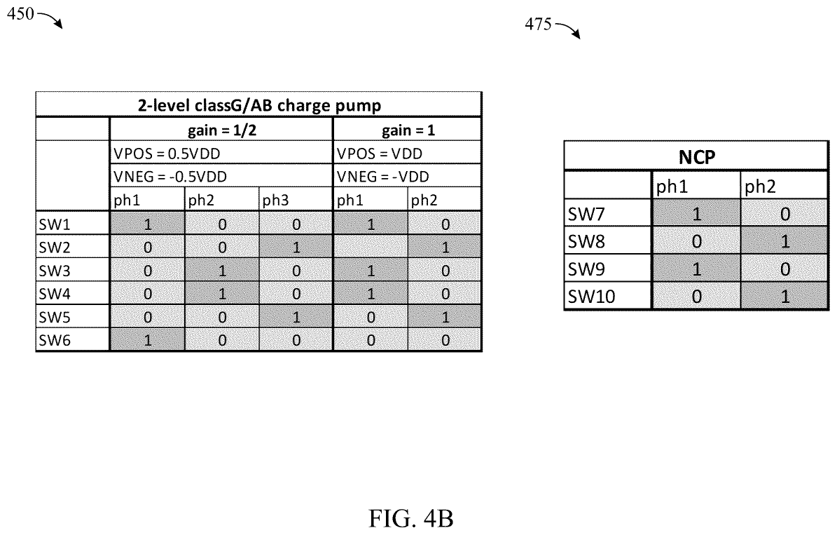

FIG. 4A is a circuit diagram of an example power supply circuit architecture 400 for implementing the first charge pump 320 and the second charge pump 330 of FIG. 3, in accordance with certain aspects of the present disclosure.

The first charge pump 320 may include a number of nodes (e.g., an input voltage node labeled “VDD,” the reference potential node GND, and the first power supply node VPOS) coupled to a first terminal (labeled “C1P”) of the first capacitive element C1 via a number of switches (e.g., SW1, SW2, and SW3, respectively), as illustrated in FIG. 4A. The first charge pump 320 may also include a number of nodes (e.g., the reference potential node GND, the second power supply node VNEG, and the first power supply node VPOS) coupled to a second terminal (labeled “C1N”) of the first capacitive element C1 via a number of switches (e.g., SW4, SW5, and SW6, respectively), also as illustrated in FIG. 4A. The input voltage node VDD may provide the input power supply voltage for the charge pumps 320, 330.

The second charge pump 330 may include a number of nodes (e.g., the input voltage node VDD and the reference potential node GND) coupled to a first terminal (labeled “C2P”) of the second capacitive element C2 via a number of switches (e.g., SW7 and SW8, respectively), as illustrated in FIG. 4A. The second charge pump 330 may also include a number of nodes (e.g., the reference potential node GND and the third power supply node VNEG_DAC) coupled to a second terminal (labeled “C2N”) of the second capacitive element C2 via a number of switches (e.g., SW9 and SW10, respectively), also as illustrated in FIG. 4A.

FIG. 4B illustrates tables 450, 475 that display the switching states of switches SW1 to SW10 during different phases for controlling the first charge pump 320 and the second charge pump 330 (the NCP) of FIGS. 3 and 4A, in accordance with certain aspects of the present disclosure.

As described above, the positive voltage at the first power supply node VPOS may be complementary to the negative voltage at the second power supply node VNEG. According to certain aspects, the positive voltage at the first power supply node VPOS may be one-half of the input voltage at the input voltage node VDD (e.g., VPOS=VDD/2), and the negative voltage at the second power supply node VNEG may be one-half of the input voltage at the input voltage node VDD (e.g., VNEG=−VDD/2). In these aspects (when the charge pump gain=½), the first charge pump 320 may be configured to generate the positive voltage at the first power supply node VPOS and the negative voltage at the second power supply node VNEG over the course of three consecutive phases. For example, and as illustrated in table 450, switches SW1 and SW6 may be closed, and switches SW2, SW3, SW4, and SW5 may be open during the first phase (e.g., labeled “ph1”). In this manner, the input voltage is applied across the first capacitive element C1 (from the input voltage node VDD to the first power supply node VPOS) during the first phase to generate a capacitor voltage. During the second phase (e.g., labeled “ph2”), switches SW3 and SW4 may be closed, and switches SW1, SW2, SW5, and SW6 may be open. In this manner, the capacitor voltage across the first capacitive element C1 is applied between the first power supply node VPOS and the reference potential node GND, such that the positive voltage at the first power supply node VPOS is one-half of the input voltage. During the third phase (e.g., labeled “ph3”), switches SW2 and SW5 may be closed, and switches SW1, SW3, SW4, and SW6 may be open. In this manner, the capacitor voltage across the first capacitive element C1 is applied from the reference potential node GND to the second power supply node VNEG during the second phase, effectively applying the capacitor voltage in reverse to generate the negative voltage at the second power supply node VNEG that is the complement of the positive voltage at the first power supply node VPOS (e.g., VNEG=−VDD/2).

According to certain aspects, the positive voltage at the first power supply node VPOS may be equal to the input voltage at the input voltage node VDD (e.g., VPOS=VDD), and the negative voltage at the second power supply node VNEG may be equal to the input voltage at the input voltage node VDD (e.g., VNEG=−VDD). In these aspects (when the charge pump gain=1), the first charge pump 320 may be configured to generate the positive voltage at the first power supply node VPOS and the negative voltage at the second power supply node VNEG over the course of two consecutive phases. For example, and as illustrated in table 450, during the first phase (e.g., labeled “ph1”), switches SW1, SW3, and SW4 may be closed, and switches SW2, SW5, and SW6 may be open. In this manner, the input voltage is applied across the first capacitive element C1 (from the input voltage node VDD to the reference potential node GND) to generate a capacitor voltage, and the input voltage node is shorted to the first power supply node VPOS such that VPOS=VDD, during the first phase. During the second phase (e.g., labeled “ph2”), switches SW2 and SW5 may be closed, and switches SW1, SW3, SW4, and SW6 may be open. In this manner, the capacitor voltage across the first capacitive element C1 is applied from the reference potential node GND to the second power supply node VNEG during the second phase, effectively applying the capacitor voltage in reverse to generate the negative voltage at the second power supply node VNEG that is the complement of the positive voltage at the first power supply node VPOS (e.g., VNEG=−VDD).

According to certain aspects, the negative voltage at the third power supply node VNEG_DAC may be a fixed negative voltage. In these aspects, the second charge pump 330 may be configured to generate the negative voltage at the third power supply node VNEG_DAC for powering the DAC 108 over the course of two consecutive phases. For example, and as illustrated in table 475, switches SW7 and SW9 may be closed, and switches SW8 and SW10 may be open during the first phase (e.g., labeled “ph1”). In this manner, the input voltage is applied across the second capacitive element C2 (from the input voltage node VDD to the reference potential node GND) during the first phase. During the second phase (e.g., labeled “ph2”), switches SW8 and SW10 may be closed, and switches SW7 and SW9 may be open. In this manner, the capacitor voltage across the second capacitive element C2 is applied from the reference potential node GND to the third power supply node VNEG_DAC during the second phase, effectively applying the capacitor voltage in reverse to generate the negative voltage at the third power supply node VNEG_DAC.

However, in order to generate the power supply voltages for the audio system 100 (e.g., the positive voltage at the first power supply node VPOS and the first negative voltage at the second power supply node VNEG for powering the amplifier 110, and the second negative voltage at the third power supply node VNEG_DAC for powering the DAC 108), the power supply circuit architecture 400 with the two charge pumps 320, 330 may call for at least four IC pins, two capacitive elements C1, C2, and extra electrostatic discharge (ESD) protection for the IC and printed circuit board (PCB) areas. Accordingly, certain aspects of the present disclosure provide a power supply architecture with fewer IC pins, fewer capacitive elements, and less ESD protection.

Certain aspects of the present disclosure provide the power supply voltages for an audio system (or other system) using a power supply circuit implemented as a single charge pump (e.g., a class-G charge pump) with a single capacitive element. Such a power supply circuit may generate the power supplies for both an amplifier (e.g., amplifier 110 of the audio system 100) and a DAC (e.g., DAC 108 of the audio system 100). Specifically, the power supply circuit may generate the positive voltage at the first power supply node VPOS, the first negative voltage at the second power supply node VNEG, and the second negative voltage at the third power supply node VNEG_DAC, as illustrated in the figures and described below.

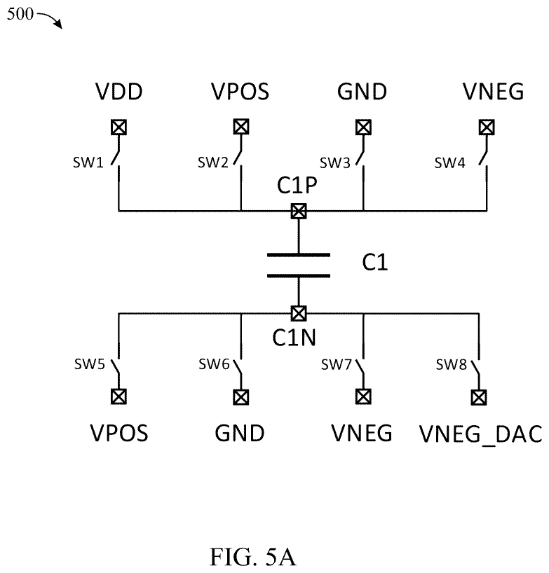

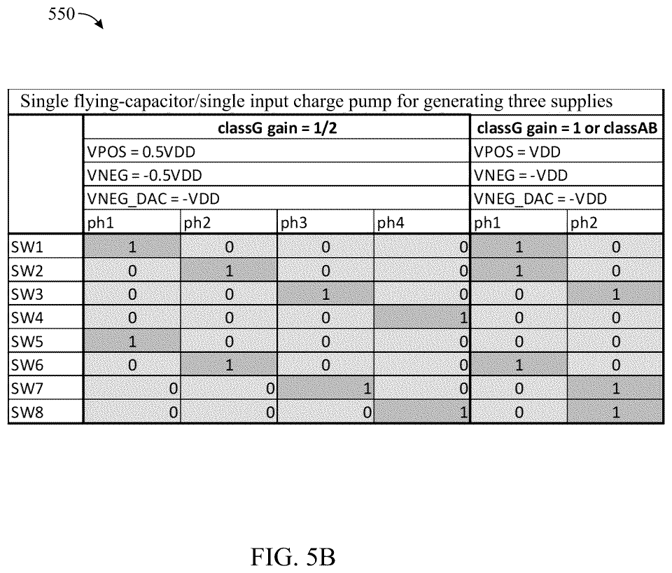

FIG. 5A is a circuit diagram of an example power supply circuit 500 configured to provide multiple power supply voltages, in accordance with certain aspects of the present disclosure. The power supply circuit 500 may be implemented as a single charge pump with a single capacitive element.

The power supply circuit 500 may include a first common node (labeled “C1P”) for coupling to a first terminal of a capacitive element C1 (which may also be referred to as a “switched capacitor” or a “flying capacitor”), a second common node (labeled “C1N”) for coupling to a second terminal of the capacitive element C1, and eight switches (e.g., SW1, SW2, SW3, SW4, SW5, SW6, SW7, SW8). The capacitive element C1 may be implemented by one or more capacitors. The first switch SW1 may be coupled between the input voltage node VDD and the first common node C1P, and the second switch SW2 may be coupled between the first power supply node VPOS and the first common node C1P. The third switch SW3 may be coupled between the reference potential node GND and the first common node C1P, and the fourth switch SW4 may be coupled between the second power supply node VNEG and the first common node C1P. In this manner, the four nodes (e.g., VDD, VPOS, GND, and VNEG) may be selectively coupled to the first common node C1P and the first terminal of the capacitive element C1 via a number of switches (e.g., SW1, SW2, SW3, and SW4), as illustrated in FIG. 5A.

The fifth switch SW5 of the power supply circuit 500 may be coupled between the first power supply node VPOS and the second common node C1N, and the sixth switch SW6 may be coupled between the reference potential node GND and the second common node C1N. The seventh switch SW7 may be coupled between the second power supply node VNEG and the second common node C1N, and the eighth switch SW8 may be coupled between the third power supply node VNEG_DAC and the second common node C1N. In this manner, the four nodes (e.g., VPOS, GND, VNEG, and VNEG_DAC) may be selectively coupled to the second common node C1N and the second terminal of the capacitive element C1 via a number of switches (e.g., SW5, SW6, SW7, and SW8), as illustrated in FIG. 5A.

The first, second, third, fourth, fifth, sixth, seventh, and eighth switches SW1, SW2, SW3, SW4, SW5, SW6, SW7, SW8 may be controlled to generate a positive voltage at the first power supply node VPOS, a first negative voltage at the second power supply node VNEG, and a second negative voltage at the third power supply node VNEG_DAC. In certain aspects, the first negative voltage may be complementary to the positive voltage. The positive voltage at the first power supply node VPOS and the first negative voltage at the second power supply node VNEG may be complementary dynamic voltages (e.g., for powering a class-G amplifier with different power supply voltages) and may be selectively switch between: (i) being equal to the magnitude of the input voltage at the input voltage node VDD (e.g., ±VDD) or being one-half the magnitude of the input voltage (e.g., ±VDD/2). In certain aspects, the second negative voltage at the third power supply node VNEG_DAC may be a fixed negative voltage. The second negative voltage at the third power supply node VNEG_DAC may be equal to the input voltage at the input voltage node VDD (e.g., VNEG_DAC=−VDD).

FIG. 5B illustrates a table 550 that displays the operation of the switching states of switches SW1 to SW8 during different phases for controlling the power supply circuit 500 of FIG. 5A, in accordance with certain aspects of the present disclosure.

According to certain aspects, the positive voltage at the first power supply node VPOS may be selected to be one-half of the input voltage at the input voltage node VDD (e.g., VPOS=VDD/2), and the negative voltage at the second power supply node VNEG may be selected to be one-half of the input voltage at the input voltage node VDD (e.g., VNEG=−VDD/2). In these aspects (when the power supply circuit gain=½), the power supply circuit 500 may be configured to generate the complementary voltages for the first and second power supply nodes VPOS, VNEG and the negative voltage for the third power supply node VNEG_DAC over the course of four consecutive phases.

For example, and as illustrated in table 550, the first switch SW1 and the fifth switch SW5 may be closed, and the second switch SW2, the third switch SW3, the fourth switch SW4, the sixth switch SW6, the seventh switch SW7, and the eighth switch SW8 may be open, during the first phase (labeled “ph1”). In this manner, the switching states of the eight switches may be controlled to charge the capacitive element C1 with the input voltage from the input voltage node VDD referenced to the first power supply node VPOS to generate a capacitor voltage across the capacitive element C1.

During the second phase (labeled “ph2”), the second switch SW2 and the sixth switch SW6 may be closed, and the first switch SW1, the third switch SW3, the fourth switch SW4, the fifth switch SW5, the seventh switch SW7, and the eighth switch SW8 may be open. In this manner, the switching states of the eight switches may be controlled to apply the capacitor voltage referenced to the reference potential node GND, such that the positive voltage at the first power supply node VPOS is one-half of the input voltage (e.g., VPOS=VDD/2).

During the third phase (labeled “ph3”), the third switch SW3 and the seventh switch SW7 may be closed, and the first switch SW1, the second switch SW2, the fourth switch SW4, the fifth switch SW5, the sixth switch SW6, and the eighth switch SW8 may be open. In this manner, the switching states of the eight switches may be controlled to apply the capacitor voltage referenced to the reference potential node GND in reverse to generate the negative voltage at the second power supply node VNEG that is the complement of the positive voltage at the first power supply node VPOS (e.g., VNEG=−VDD/2).

During the fourth phase (labeled “ph4”), the fourth switch SW4 and the eighth switch SW8 may be closed, and the first switch SW1, the second switch SW2, the third switch SW3, the fifth switch SW5, the sixth switch SW6, and the seventh switch SW7 may be open. In this manner, the switching states of the eight switches may be controlled to add the capacitor voltage in reverse to the negative voltage at the second power supply node VNEG to generate the negative voltage at the third power supply node VNEG_DAC (e.g., VNEG_DAC=−VDD).

According to certain aspects, the positive voltage at the first power supply node VPOS may be selected to be equal to the input voltage at the input voltage node VDD (e.g., VPOS=VDD), and the first negative voltage at the second power supply node VNEG may be selected to be equal to the input voltage at the input voltage node VDD (e.g., VNEG=−VDD). In these aspects (when the power supply circuit gain=1), the power supply circuit 500 may be configured to generate the complementary voltages for the first and second power supply nodes VPOS, VNEG and the negative voltage for the third power supply node VNEG_DAC over the course of two consecutive phases.

For example, and as illustrated in table 550, the first switch SW1, the second switch SW2, and the sixth switch SW6 may be closed, and the third switch SW3, the fourth switch SW4, the fifth switch SW5, the seventh switch SW7, and the eighth switch SW8 may be open, during the first phase (labeled “ph1”). In this manner, the switching states of the eight switches may be controlled during the first phase to apply the input voltage across the capacitive element C1 (from the input voltage node VDD to the reference potential node GND) to generate a capacitive voltage across the capacitive element C1 referenced to the reference potential node GND and to short the input voltage node VDD to the first power supply node VPOS such that VPOS=VDD.

During the second phase (labeled “ph2”), the third switch SW3, the seventh switch SW7, and the eighth switch SW8 may be closed, and the first switch SW1, the second switch SW2, the fourth switch SW4, the fifth switch SW5, and the sixth switch SW6 may be open. In this manner, the switching states of the eight switches may be controlled during the second phase to apply the capacitor voltage referenced to the reference potential node GND in reverse to generate the negative voltage at the second power supply node VNEG and to short the second power supply node VNEG to the third power supply node VNEG_DAC such that VNEG=VNEG_DAC=−VDD.

Because the power supply circuit 500 can generate the same power supply voltages as the power supply circuit architecture 400, an audio or other system using the power supply circuit 500 need not include another charge pump (e.g., the second charge pump 330, which may be a NCP) with another capacitive element (e.g., the second capacitive element C2). In addition, the power supply circuit 500 may use two fewer pins (when implemented in an IC) and two fewer switches than the architecture 400, reducing the bill of materials (BOM), area, and cost and simplifying the PCB break-out.

### Example Operations for Supplying Power

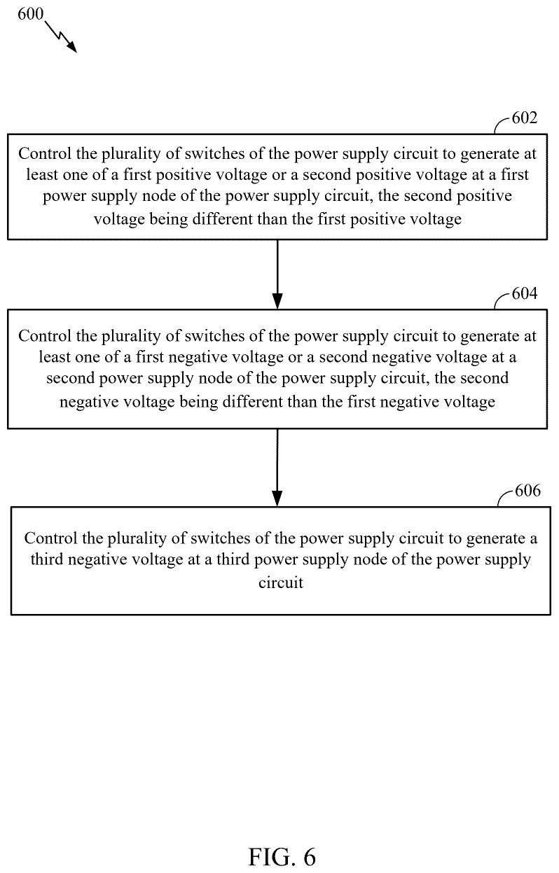

FIG. 6 is a flow diagram of example operations 600 for supplying power, in accordance with certain aspects of the present disclosure. The operations 600 may be performed by a power supply circuit (e.g., the power supply circuit 500 of FIG. 5A) that includes a plurality of switches (e.g., SW1, SW2, SW3, SW4, SW5, SW6, SW7, SW8) coupled to a capacitive element (e.g., capacitive element C1) and/or control logic that is part of or external to the power supply circuit.

The operations 600 may include, at block 602, controlling the plurality of switches of the power supply circuit to generate at least one of a first positive voltage (e.g., +VDD) or a second positive voltage (e.g., +VDD/2) at a first power supply node (e.g., first power supply node VPOS) of the power supply circuit. The second positive voltage is different than the first positive voltage.

The operations 600 may include, at block 604, controlling the plurality of switches of the power supply circuit to generate at least one of a first negative voltage (e.g., −VDD) or a second negative voltage (e.g., −VDD/2) at a second power supply node (e.g., second power supply node VNEG) of the power supply circuit. The second negative voltage is different than the first negative voltage. In certain aspects, the second positive voltage may be one-half of the first positive voltage, and the second negative voltage may be one-half of the first negative voltage.

The operations 600 may include, at block 606, controlling the plurality of switches of the power supply circuit to generate a third negative voltage (e.g., −VDD) at a third power supply node (e.g., third power supply node VNEG_DAC) of the power supply circuit. In certain aspects, the third negative voltage may be a fixed negative voltage.

According to certain aspects, the second positive voltage may be one-half of an input voltage at an input voltage node (e.g., input voltage node VDD) of the power supply circuit (e.g., in cases where gain=½). In certain aspects, controlling the plurality of switches to generate the at least one of the first positive voltage or the second positive voltage may include: (i) during a first phase (e.g., first phase ph1), controlling the plurality of switches to charge the capacitive element with the input voltage referenced to the first power supply node to generate a capacitor voltage across the capacitive element; and (ii) during a second phase (e.g., second phase ph2), controlling the plurality of switches to apply the capacitor voltage referenced to a reference potential node (e.g., reference potential node GND) of the power supply circuit to generate the second positive voltage at the first power supply node. In some aspects, controlling the plurality of switches to generate the at least one of the first negative voltage or the second negative voltage may involve, during a third phase (e.g., third phase ph3), controlling the plurality of switches to apply the capacitor voltage referenced to the reference potential node in reverse to generate the second negative voltage at the second power supply node. In some aspects, controlling the plurality of switches to generate the third negative voltage may include, during a fourth phase (e.g., fourth phase ph4), controlling the plurality of switches to add the capacitor voltage in reverse to the second negative voltage to generate the third negative voltage at the third power supply node.

According to certain aspects, the first positive voltage may equal an input voltage at an input voltage node (e.g., input voltage node VDD) of the power supply circuit (e.g., in cases where gain=1). In this case, the third negative voltage may equal the first negative voltage. In certain aspects, controlling the plurality of switches to generate the at least one of the first positive voltage or the second positive voltage may include, during a first phase (e.g., first phase ph1), controlling the plurality of switches to charge the capacitive element with the input voltage to generate a capacitor voltage across the capacitive element referenced to a reference potential node (e.g., reference potential node GND) of the power supply circuit and to short the input voltage node to the first power supply node. In some aspects, controlling the plurality of switches to generate the at least one of the first negative voltage or the second negative voltage and controlling the plurality of switches to generate the third negative voltage may include, during a second phase (e.g., second phase ph2), controlling the plurality of switches to apply the capacitor voltage referenced to the reference potential node in reverse to generate the first negative voltage and to short the second power supply node to the third power supply node.

### Example Aspects

In addition to the various aspects described above, specific combinations of aspects are within the scope of the disclosure, some of which are detailed below:

Aspect 1: A power supply circuit comprising: a first common node for coupling to a first terminal of a capacitive element; a first switch coupled between an input voltage node and the first common node; a second switch coupled between a first power supply node and the first common node; a third switch coupled between a reference potential node and the first common node; and a fourth switch coupled between a second power supply node and the first common node.

Aspect 2: The power supply circuit of Aspect 1, further comprising: a second common node for coupling to a second terminal of the capacitive element; a fifth switch coupled between the first power supply node and the second common node; a sixth switch coupled between the reference potential node and the second common node; a seventh switch coupled between the second power supply node and the second common node; and an eighth switch coupled between a third power supply node and the second common node.

Aspect 3: The power supply circuit of Aspect 2, wherein the first, second, third, fourth, fifth, sixth, seventh, and eighth switches are configured to be controlled to generate: a positive voltage at the first power supply node; a first negative voltage at the second power supply node, the first negative voltage being complementary to the positive voltage; and a second negative voltage at the third power supply node.

Aspect 4: The power supply circuit of Aspect 3, wherein the second negative voltage is a fixed negative voltage.

Aspect 5: The power supply circuit of Aspect 3 or 4, wherein the positive voltage and the first negative voltage are complementary dynamic voltages.

Aspect 6: The power supply circuit according to any of Aspects 3-5, wherein: the positive voltage is one-half of an input voltage at the input voltage node; during a first phase, the first switch and the fifth switch are configured to be closed and the second switch, the third switch, the fourth switch, the sixth switch, the seventh switch, and the eighth switch are configured to be open; during a second phase, the second switch and the sixth switch are configured to be closed and the first switch, the third switch, the fourth switch, the fifth switch, the seventh switch, and the eighth switch are configured to be open; during a third phase, the third switch and the seventh switch are configured to be closed and the first switch, the second switch, the fourth switch, the fifth switch, the sixth switch, and the eighth switch are configured to be open; and during a fourth phase, the fourth switch and the eighth switch are configured to be closed and the first switch, the second switch, the third switch, the fifth switch, the sixth switch, and the seventh switch are configured to be open.

Aspect 7: The power supply circuit according to any of Aspects 3-5, wherein: the positive voltage equals an input voltage at the input voltage node; during a first phase, the first switch, the second switch, and the sixth switch are configured to be closed and the third switch, the fourth switch, the fifth switch, the seventh switch, and the eighth switch are configured to be open; and during a second phase, the third switch, the seventh switch, and the eighth switch are configured to be closed and the first switch, the second switch, the fourth switch, the fifth switch, and the sixth switch are configured to be open.

Aspect 8: A power supply circuit comprising: a first common node for coupling to a terminal of a capacitive element; a first switch coupled between a first power supply node and the first common node; a second switch coupled between a reference potential node and the first common node; a third switch coupled between a second power supply node and the first common node; and a fourth switch coupled between a third power supply node and the first common node.

Aspect 9: The power supply circuit of Aspect 8, wherein the first, second, third, and fourth switches are configured to be controlled to generate: a positive voltage at the first power supply node; a first negative voltage at the second power supply node, the first negative voltage being complementary to the positive voltage; and a second negative voltage at the third power supply node.

Aspect 10: The power supply circuit of Aspect 9, wherein the second negative voltage is a fixed negative voltage.

Aspect 11: The power supply circuit of Aspect 9 or 10, wherein the positive voltage and the first negative voltage are complementary dynamic voltages.

Aspect 12: The power supply circuit according to any of Aspects 9-11, further comprising an input voltage node selectively coupled to another terminal of the capacitive element, wherein: the positive voltage is one-half of an input voltage at the input voltage node; during a first phase, the first switch is configured to be closed and the second switch, the third switch, and the fourth switch are configured to be open; during a second phase, the second switch is configured to be closed and the first switch, the third switch, and the fourth switch are configured to be open; during a third phase, the third switch is configured to be closed and the first switch, the second switch, and the fourth switch are configured to be open; and during a fourth phase, the fourth switch is configured to be closed and the first switch, the second switch, and the third switch are configured to be open.

Aspect 13: The power supply circuit according to any of Aspects 9-11, further comprising an input voltage node selectively coupled to another terminal of the capacitive element, wherein: the positive voltage equals an input voltage at the input voltage node; during a first phase, the second switch is configured to be closed and the first switch, the third switch, and the fourth switch are configured to be open; and during a second phase, the third switch and the fourth switch are configured to be closed and the first switch and the second switch are configured to be open.

Aspect 14: A power supply circuit comprising: a capacitive element; and a plurality of switches coupled to the capacitive element and configured to be controlled to generate: at least one of a first positive voltage or a second positive voltage at a first power supply node, the second positive voltage being different than the first positive voltage; at least one of a first negative voltage or a second negative voltage at a second power supply node, the second negative voltage being different than the first negative voltage; and a third negative voltage at a third power supply node.

Aspect 15: The power supply circuit of Aspect 14, wherein the third negative voltage is a fixed negative voltage.

Aspect 16: The power supply circuit of Aspect 14 or 15, wherein the second positive voltage is one-half of the first positive voltage and wherein the second negative voltage is one-half of the first negative voltage.

Aspect 17: The power supply circuit according to any of Aspects 14-16, further comprising: an input voltage node; and a reference potential node, wherein: the second positive voltage is one-half of an input voltage at the input voltage node; during a first phase, the plurality of switches is configured to be controlled to charge the capacitive element with the input voltage referenced to the first power supply node to generate a capacitor voltage across the capacitive element; during a second phase, the plurality of switches is configured to be controlled to apply the capacitor voltage referenced to the reference potential node to generate the second positive voltage at the first power supply node; during a third phase, the plurality of switches is configured to be controlled to apply the capacitor voltage referenced to the reference potential node in reverse to generate the second negative voltage at the second power supply node; and during a fourth phase, the plurality of switches is configured to be controlled to add the capacitor voltage in reverse to the second negative voltage to generate the third negative voltage at the third power supply node.

Aspect 18: The power supply circuit according to any of Aspects 14-16, further comprising: an input voltage node; and a reference potential node, wherein: the first positive voltage equals an input voltage at the input voltage node; the third negative voltage equals the first negative voltage; during a first phase, the plurality of switches is configured to be controlled to charge the capacitive element with the input voltage to generate a capacitor voltage across the capacitive element referenced to the reference potential node and to short the input voltage node to the first power supply node; and during a second phase, the plurality of switches is configured to be controlled to apply the capacitor voltage referenced to the reference potential node in reverse to generate the first negative voltage and to short the second power supply node to the third power supply node.

Aspect 19: A circuit comprising: an amplifier; a digital-to-analog converter (DAC); a charge pump (CP) configured to generate at least three power supply voltages; and at least three different power supply rails coupled between the CP and at least one of the amplifier and the DAC and configured to power the amplifier and the DAC with the at least three power supply voltages.

Aspect 20: The circuit of Aspect 19, wherein the at least three power supply voltages, which the CP is configured to generate, comprise: a positive voltage; a first negative voltage; and a second negative voltage.

Aspect 21: The circuit of Aspect 20, wherein the second negative voltage comprises a fixed negative voltage configured to power the DAC.

Aspect 22: The circuit of Aspect 20 or 21, wherein the positive voltage and the first negative voltage are complementary dynamic voltages configured to power the amplifier.

Aspect 23: The circuit according to any of Aspects 19-22, wherein the CP comprises: a capacitive element; a first common node for coupling to a first terminal of the capacitive element; a first switch coupled between an input voltage node and the first common node; a second switch coupled between a first power supply node having the positive voltage and the first common node; a third switch coupled between a reference potential node and the first common node; a fourth switch coupled between a second power supply node having the first negative voltage and the first common node; a second common node for coupling to a second terminal of the capacitive element; a fifth switch coupled between the first power supply node and the second common node; a sixth switch coupled between the reference potential node and the second common node; a seventh switch coupled between the second power supply node and the second common node; and an eighth switch coupled between a third power supply node having the second negative voltage and the second common node.

Aspect 24: The circuit of Aspect 23, wherein: the positive voltage is one-half of an input voltage at the input voltage node; during a first phase for the CP, the first switch and the fifth switch are configured to be closed and the second switch, the third switch, the fourth switch, the sixth switch, the seventh switch, and the eighth switch are configured to be open; during a second phase for the CP, the second switch and the sixth switch are configured to be closed and the first switch, the third switch, the fourth switch, the fifth switch, the seventh switch, and the eighth switch are configured to be open; during a third phase for the CP, the third switch and the seventh switch are configured to be closed and the first switch, the second switch, the fourth switch, the fifth switch, the sixth switch, and the eighth switch are configured to be open; and during a fourth phase for the CP, the fourth switch and the eighth switch are configured to be closed and the first switch, the second switch, the third switch, the fifth switch, the sixth switch, and the seventh switch are configured to be open.

Aspect 25: The circuit of Aspect 23, wherein: the positive voltage equals an input voltage at the input voltage node; during a first phase for the CP, the first switch, the second switch, and the sixth switch are configured to be closed and the third switch, the fourth switch, the fifth switch, the seventh switch, and the eighth switch are configured to be open; and during a second phase for the CP, the third switch, the seventh switch, and the eighth switch are configured to be closed and the first switch, the second switch, the fourth switch, the fifth switch, and the sixth switch are configured to be open.

Aspect 26: A method of supplying power with a power supply circuit comprising a plurality of switches coupled to a capacitive element, the method comprising: controlling the plurality of switches of the power supply circuit to generate at least one of a first positive voltage or a second positive voltage at a first power supply node of the power supply circuit, the second positive voltage being different than the first positive voltage; controlling the plurality of switches of the power supply circuit to generate at least one of a first negative voltage or a second negative voltage at a second power supply node of the power supply circuit, the second negative voltage being different than the first negative voltage; and controlling the plurality of switches of the power supply circuit to generate a third negative voltage at a third power supply node of the power supply circuit.

Aspect 27: The method of Aspect 26, wherein the third negative voltage is a fixed negative voltage.

Aspect 28: The method of Aspect 26 or 27, wherein the second positive voltage is one-half of the first positive voltage and wherein the second negative voltage is one-half of the first negative voltage.

Aspect 29: The method according to any of Aspects 26-28, wherein: the second positive voltage is one-half of an input voltage at an input voltage node of the power supply circuit; controlling the plurality of switches to generate the at least one of the first positive voltage or the second positive voltage comprises: during a first phase, controlling the plurality of switches to charge the capacitive element with the input voltage referenced to the first power supply node to generate a capacitor voltage across the capacitive element; during a second phase, controlling the plurality of switches to apply the capacitor voltage referenced to a reference potential node of the power supply circuit to generate the second positive voltage at the first power supply node; controlling the plurality of switches to generate the at least one of the first negative voltage or the second negative voltage comprises, during a third phase, controlling the plurality of switches to apply the capacitor voltage referenced to the reference potential node in reverse to generate the second negative voltage at the second power supply node; and controlling the plurality of switches to generate the third negative voltage comprises, during a fourth phase, controlling the plurality of switches to add the capacitor voltage in reverse to the second negative voltage to generate the third negative voltage at the third power supply node.

Aspect 30: The method according to any of Aspects 26-28, wherein: the first positive voltage equals an input voltage at an input voltage node of the power supply circuit; the third negative voltage equals the first negative voltage; controlling the plurality of switches to generate the at least one of the first positive voltage or the second positive voltage comprises, during a first phase, controlling the plurality of switches to charge the capacitive element with the input voltage to generate a capacitor voltage across the capacitive element referenced to a reference potential node of the power supply circuit and to short the input voltage node to the first power supply node; and controlling the plurality of switches to generate the at least one of the first negative voltage or the second negative voltage and controlling the plurality of switches to generate the third negative voltage comprise, during a second phase, controlling the plurality of switches to apply the capacitor voltage referenced to the reference potential node in reverse to generate the first negative voltage and to short the second power supply node to the third power supply node.

### Additional Considerations

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes and variations may be made in the arrangement, operation, and details of the methods and apparatus described above without departing from the scope of the claims.

What is claimed is:

1. A power supply circuit comprising:
a first common node for coupling to a first terminal of a capacitive element;
a first switch coupled between an input voltage node and the first common node;
a second switch coupled between a first power supply node and the first common node;
a third switch coupled between a reference potential node and the first common node; and
a fourth switch coupled between a second power supply node and the first common node.

2. The power supply circuit of claim 1, further comprising:
a second common node for coupling to a second terminal of the capacitive element;
a fifth switch coupled between the first power supply node and the second common node;
a sixth switch coupled between the reference potential node and the second common node;
a seventh switch coupled between the second power supply node and the second common node; and
an eighth switch coupled between a third power supply node and the second common node.

3. The power supply circuit of claim 2, wherein the first, second, third, fourth, fifth, sixth, seventh, and eighth switches are configured to be controlled to generate:
a positive voltage at the first power supply node;
a first negative voltage at the second power supply node, the first negative voltage being complementary to the positive voltage; and
a second negative voltage at the third power supply node.

4. The power supply circuit of claim 3, wherein the second negative voltage is a fixed negative voltage.

5. The power supply circuit of claim 4, wherein the positive voltage and the first negative voltage are complementary dynamic voltages.

6. The power supply circuit of claim 3, wherein:
the positive voltage is one-half of an input voltage at the input voltage node;
during a first phase, the first switch and the fifth switch are configured to be closed and the second switch, the third switch, the fourth switch, the sixth switch, the seventh switch, and the eighth switch are configured to be open;
during a second phase, the second switch and the sixth switch are configured to be closed and the first switch, the third switch, the fourth switch, the fifth switch, the seventh switch, and the eighth switch are configured to be open;
during a third phase, the third switch and the seventh switch are configured to be closed and the first switch, the second switch, the fourth switch, the fifth switch, the sixth switch, and the eighth switch are configured to be open; and
during a fourth phase, the fourth switch and the eighth switch are configured to be closed and the first switch, the second switch, the third switch, the fifth switch, the sixth switch, and the seventh switch are configured to be open.

7. The power supply circuit of claim 3, wherein:
the positive voltage equals an input voltage at the input voltage node;
during a first phase, the first switch, the second switch, and the sixth switch are configured to be closed and the third switch, the fourth switch, the fifth switch, the seventh switch, and the eighth switch are configured to be open; and
during a second phase, the third switch, the seventh switch, and the eighth switch are configured to be closed and the first switch, the second switch, the fourth switch, the fifth switch, and the sixth switch are configured to be open.

8. A power supply circuit comprising:
a first common node for coupling to a terminal of a capacitive element;
a first switch coupled between a first power supply node and the first common node;
a second switch coupled between a reference potential node and the first common node;
a third switch coupled between a second power supply node and the first common node; and
a fourth switch coupled between a third power supply node and the first common node.

9. The power supply circuit of claim 8, wherein the first, second, third, and fourth switches are configured to be controlled to generate:
a positive voltage at the first power supply node;
a first negative voltage at the second power supply node, the first negative voltage being complementary to the positive voltage; and
a second negative voltage at the third power supply node.

10. The power supply circuit of claim 9, wherein the second negative voltage is a fixed negative voltage.

11. The power supply circuit of claim 10, wherein the positive voltage and the first negative voltage are complementary dynamic voltages.

12. The power supply circuit of claim 9, further comprising an input voltage node selectively coupled to another terminal of the capacitive element, wherein:
the positive voltage is one-half of an input voltage at the input voltage node;
during a first phase, the first switch is configured to be closed and the second switch, the third switch, and the fourth switch are configured to be open;
during a second phase, the second switch is configured to be closed and the first switch, the third switch, and the fourth switch are configured to be open;
during a third phase, the third switch is configured to be closed and the first switch, the second switch, and the fourth switch are configured to be open; and
during a fourth phase, the fourth switch is configured to be closed and the first switch, the second switch, and the third switch are configured to be open.

13. The power supply circuit of claim 9, further comprising an input voltage node selectively coupled to another terminal of the capacitive element, wherein:
the positive voltage equals an input voltage at the input voltage node;
during a first phase, the second switch is configured to be closed and the first switch, the third switch, and the fourth switch are configured to be open; and
during a second phase, the third switch and the fourth switch are configured to be closed and the first switch and the second switch are configured to be open.

14. A power supply circuit comprising:
a capacitive element; and
a plurality of switches coupled to the capacitive element and configured to be controlled to generate:
at least one of a first positive voltage or a second positive voltage at a first power supply node, the second positive voltage being different than the first positive voltage;
at least one of a first negative voltage or a second negative voltage at a second power supply node, the second negative voltage being different than the first negative voltage; and
a third negative voltage at a third power supply node.

15. The power supply circuit of claim 14, wherein the third negative voltage is a fixed negative voltage.

16. The power supply circuit of claim 14, wherein the second positive voltage is one-half of the first positive voltage and wherein the second negative voltage is one-half of the first negative voltage.

17. The power supply circuit of claim 14, further comprising:
an input voltage node; and
a reference potential node, wherein:
the second positive voltage is one-half of an input voltage at the input voltage node;
during a first phase, the plurality of switches is configured to be controlled to charge the capacitive element with the input voltage referenced to the first power supply node to generate a capacitor voltage across the capacitive element;
during a second phase, the plurality of switches is configured to be controlled to apply the capacitor voltage referenced to the reference potential node to generate the second positive voltage at the first power supply node;
during a third phase, the plurality of switches is configured to be controlled to apply the capacitor voltage referenced to the reference potential node in reverse to generate the second negative voltage at the second power supply node; and
during a fourth phase, the plurality of switches is configured to be controlled to add the capacitor voltage in reverse to the second negative voltage to generate the third negative voltage at the third power supply node.

18. The power supply circuit of claim 14, further comprising:
an input voltage node; and
a reference potential node, wherein:
the first positive voltage equals an input voltage at the input voltage node;
the third negative voltage equals the first negative voltage;
during a first phase, the plurality of switches is configured to be controlled to charge the capacitive element with the input voltage to generate a capacitor voltage across the capacitive element referenced to the reference potential node and to short the input voltage node to the first power supply node; and
during a second phase, the plurality of switches is configured to be controlled to apply the capacitor voltage referenced to the reference potential node in reverse to generate the first negative voltage and to short the second power supply node to the third power supply node.

19. A circuit comprising:
an amplifier;
a digital-to-analog converter (DAC);
a charge pump (CP) configured to generate at least three power supply voltages; and
at least three different power supply rails coupled between the CP and at least one of the amplifier and the DAC and configured to power the amplifier and the DAC with the at least three power supply voltages.

20. The circuit of claim 19, wherein the at least three power supply voltages, which the CP is configured to generate, comprise:
a positive voltage;
a first negative voltage; and
a second negative voltage.

21. The circuit of claim 20, wherein the second negative voltage comprises a fixed negative voltage configured to power the DAC.

22. The circuit of claim 21, wherein the positive voltage and the first negative voltage are complementary dynamic voltages configured to power the amplifier.

23. The circuit of claim 20, wherein the CP comprises:
a capacitive element;
a first common node for coupling to a first terminal of the capacitive element;
a first switch coupled between an input voltage node and the first common node;
a second switch coupled between a first power supply node having the positive voltage and the first common node;
a third switch coupled between a reference potential node and the first common node;
a fourth switch coupled between a second power supply node having the first negative voltage and the first common node;
a second common node for coupling to a second terminal of the capacitive element;
a fifth switch coupled between the first power supply node and the second common node;
a sixth switch coupled between the reference potential node and the second common node;
a seventh switch coupled between the second power supply node and the second common node; and
an eighth switch coupled between a third power supply node having the second negative voltage and the second common node.

24. The circuit of claim 23, wherein:
the positive voltage is one-half of an input voltage at the input voltage node;
during a first phase for the CP, the first switch and the fifth switch are configured to be closed and the second switch, the third switch, the fourth switch, the sixth switch, the seventh switch, and the eighth switch are configured to be open;
during a second phase for the CP, the second switch and the sixth switch are configured to be closed and the first switch, the third switch, the fourth switch, the fifth switch, the seventh switch, and the eighth switch are configured to be open;
during a third phase for the CP, the third switch and the seventh switch are configured to be closed and the first switch, the second switch, the fourth switch, the fifth switch, the sixth switch, and the eighth switch are configured to be open; and
during a fourth phase for the CP, the fourth switch and the eighth switch are configured to be closed and the first switch, the second switch, the third switch, the fifth switch, the sixth switch, and the seventh switch are configured to be open.

25. The circuit of claim 23, wherein:
the positive voltage equals an input voltage at the input voltage node;
during a first phase for the CP, the first switch, the second switch, and the sixth switch are configured to be closed and the third switch, the fourth switch, the fifth switch, the seventh switch, and the eighth switch are configured to be open; and
during a second phase for the CP, the third switch, the seventh switch, and the eighth switch are configured to be closed and the first switch, the second switch, the fourth switch, the fifth switch, and the sixth switch are configured to be open.
